(19) United States
(12) Patent Application Publication
(10) Pub. No.: US 2021/0407875 A1
(43) Pub. Date: Dec. 30, 2021

(54) SEMICONDUCTOR DEVICE

(71) Applicant: DENSO CORPORATION, Kariya-city (JP)

(72) Inventors: Ryota MIWA, Kariya-city (JP); Takuo NAGASE, Kariya-city (JP); Hiroshi ISHINO, Kariya-city (JP)

(21) Appl. No.: 17/468,952

(22) Filed: Sep. 8, 2021

Related U.S. Application Data
(63) Continuation of application No. PCT/JP2020/005573, filed on Feb. 13, 2020.

(30) Foreign Application Priority Data
Mar. 11, 2019 (JP) 2019-043887

(51) Int. Cl. H01L 23/31; H01L 23/00; H01L 25/065; H01L 23/495

(52) U.S. Cl. CPC H01L 23/3107; H01L 24/48; H01L 25/0652; H01L 23/49575; H01L 23/367; H01L 24/33; H01L 24/32; H01L 24/73; H01L 23/49568

(57) ABSTRACT

A semiconductor device includes at least one semiconductor element, a sealing resin body, a first main terminal, and a second main terminal. The at least one semiconductor element has, as main electrodes, a first main electrode and a second main electrode. A main current flows between the first main electrode and the second main electrode. The sealing resin body seals the at least one semiconductor element. The first main terminal is electrically connected to the first main electrode inside the sealing resin body. The second main terminal is electrically connected to the second main electrode inside the sealing resin body. Each of the first main terminal and the second main terminal extends to an outside of the sealing resin body for connecting to an external member.

### CROSS REFERENCE TO RELATED APPLICATIONS

The present application is a continuation application of International Patent Application No. PCT/JP2020/005573 filed on Feb. 13, 2020, which designated the U.S. and claims the benefit of priority from Japanese Patent Application No. 2019-043887 filed on Mar. 11, 2019. The entire disclosures of all of the above applications are incorporated herein by reference.

### TECHNICAL FIELD

The present disclosure relates to a semiconductor device.

### BACKGROUND

For example, a semiconductor device includes a semiconductor element that has a first main electrode and a second main electrode, a sealing resin body that seals the semiconductor element, and a main terminal (a terminal portion) electrically connected to the corresponding main electrode.

### SUMMARY

The present disclosure provides a semiconductor device. The semiconductor device includes at least one semiconductor element, a sealing resin body, a first main terminal, and a second main terminal. The at least one semiconductor element has, as main electrodes, a first main electrode and a second main electrode. A main current flows between the first main electrode and the second main electrode. The sealing resin body seals the at least one semiconductor element. The first main terminal is electrically connected to the first main electrode inside the sealing resin body. The second main terminal is electrically connected to the second main electrode inside the sealing resin body. Each of the first main terminal and the second main terminal extends to an outside of the sealing resin body for connecting to an external member.

### BRIEF DESCRIPTION OF DRAWINGS

The features and advantages of the present disclosure will become more apparent from the following detailed description made with reference to the accompanying drawings. In the drawings:

FIG. 1 is a diagram showing a schematic configuration of a power conversion device to which a semiconductor device according to a first embodiment is applied;

FIG. 2 is a plan view showing a semiconductor device;

FIG. 3 is a plan view of FIG. 2 as seen from an A direction;

FIG. 4 is a cross-sectional view of the semiconductor device taken along a line V-V in FIG. 2;

FIG. 5 is an enlarged view of a periphery of main terminals in FIG. 2;

FIG. 6 is a diagram showing a relationship between the number of main terminals, inductance, and terminal temperature in a reference example;

FIG. 7 is a diagram showing a proximity effect;

FIG. 8 is an enlarged view of a periphery of main terminals in a semiconductor device according to a second embodiment;

FIG. 9 is a plan view showing a semiconductor module and a laminated body;

FIG. 10 is an enlarged view of a periphery of main terminals in a semiconductor module provided with a semiconductor device according to a third embodiment;

FIG. 11 is a diagram showing a semiconductor device according to a fourth embodiment;

FIG. 12 is a cross-sectional view of the semiconductor device taken along a line VII-VII in FIG. 11;

FIG. 13 is a cross-sectional view of the semiconductor device taken along a line VIII-VIII in FIG. 11; and

FIG. 14 is an enlarged view of a region XIV shown in FIG. 11.

### DETAILED DESCRIPTION

For example, a semiconductor device includes one main terminal connected to a first main electrode and one second main terminal connected to a second main electrode as main terminals. Further reduction of inductance is required.

In the semiconductor device, all the main terminals protrude from one surface of a sealing resin body to an outside of the sealing resin body. Therefore, there is a possibility that the main terminals may be affected by a temperature rise due to electrical conduction.

The present disclosure provides a semiconductor device capable of suppressing a temperature rise of a main terminal while reducing an inductance.

An exemplary embodiment of the present disclosure provides a semiconductor device. The semiconductor device includes at least one semiconductor element, a sealing resin body, a first main terminal, and a second main terminal. The at least one semiconductor element has, as main electrodes, a first main electrode and a second main electrode. A main current flows between the first main electrode and the second main electrode. The sealing resin body seals the at least one semiconductor element. The first main terminal and the second main terminal are provided as a plurality of main terminals. The first main terminal is electrically connected to the first main electrode inside the sealing resin body. The second main terminal is electrically connected to the second main electrode inside the sealing resin body. Each of the plurality of main terminals extends to an outside of the sealing resin body for connecting to an external member. All of the plurality of main terminals protrude from one surface of the sealing resin body. The first main terminal and the second main terminal are alternately arranged in one direction orthogonal to a thickness direction of the at least one semiconductor element such that a side surface of the first main terminal and a side surface of the second main terminal face each other. A width in the one direction of each of the plurality of main terminals protruding from the one surface of the sealing resin body is greater in an external connection portion to which the external member is connected than in a boundary portion to which the sealing resin body is connected.

In the exemplary embodiment of the present disclosure, the first main terminal and the second main terminal are alternately arranged so that the side surfaces thereof face each other. In the semiconductor device, multiple pairs of side surfaces of the first main terminal and the second main terminal facing each other are formed. Thereby, it is possible to reduce the inductance.

On the other hand, in a configuration in which all the main terminals are drawn out from the one surface of the sealing resin body, the width of a region where all the terminals are arranged is set to be smaller than the width of the one surface at the boundary portion. As a comparative example, it is assumed that the main terminals extend in a direction orthogonal to one direction over the inside and outside of the sealing resin body. In this configuration, the proportion of the gap between the terminals increases as the number of main terminals increases in order to reduce the inductance. Since the electrical conduction region of the main terminals becomes small, for example, it becomes difficult for DC current to flow, and there is a difficulty that the main terminals may be affected by the temperature rise due to the electrical conduction. The DC current is a current that flows in a steady state when the semiconductor element is on.

In the semiconductor device of the exemplary embodiment of the present disclosure, the width of the external connection portion is greater than the width of the boundary portion in the protruding portion of the main terminal. Compared with the configuration in which the main terminal is pulled out from one surface of the sealing resin body with the same width, the electrical conduction region of the main terminal is larger. Further, outside the sealing resin body, the heat dissipation area by the main terminal is increased. Therefore, it is possible to suppress the temperature rise of the main terminal.

With this configuration, the semiconductor device can suppress the temperature rise of the main terminal while reducing an inductance.

Embodiments will be described with reference to the drawings. In the multiple embodiments, functionally and/or structurally corresponding portions are designated with the same reference numerals. In the multiple embodiments, the descriptions can be incorporated into each other. In the following description, a thickness direction of a semiconductor element is shown as a Z direction and a direction orthogonal to the Z direction is shown as an X direction. A direction orthogonal to both of the Z direction and the X direction is shown as a Y direction. Unless otherwise specified, a shape along an XY plane defined by the X-direction and the Y-direction is a planar shape.

### First Embodiment

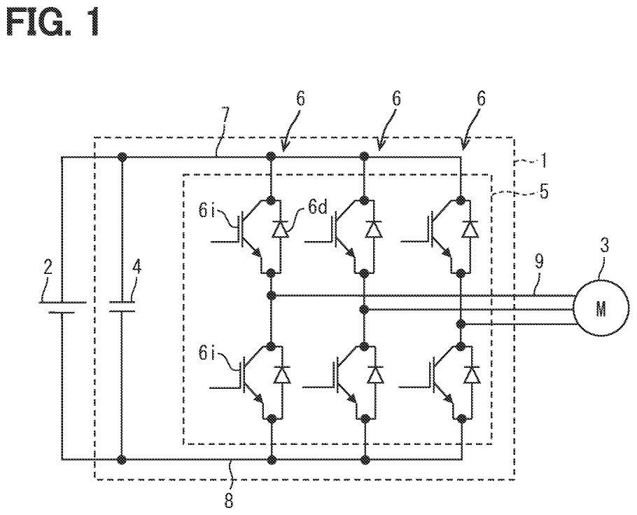

First, a power conversion device employing a semiconductor device will be described with reference to FIG. 1.

### (Power Converter)

An electric power conversion device 1 shown in FIG. 1 is mounted on, for example, an electric vehicle or a hybrid vehicle. The electric power conversion device 1 performs electric power conversion between a direct current (DC) power source 2 and a motor generator 3.

The DC power source 2 is a secondary battery capable of charging and discharging such as a lithium ion battery or a nickel hydrogen battery. The motor generator 3 is a three-phase alternating current (AC) type rotating electric machine. The motor generator 3 functions as a vehicle driving power source, that is, an electric motor. The motor generator 3 functions also as a generator during regeneration.

The electric power conversion device 1 includes a smoothing capacitor 4 and an inverter 5 as a power converter. A positive electrode terminal of the smoothing capacitor 4 is connected to a positive electrode of the DC power source 2, which is a high potential side electrode of the DC power source 2. A negative electrode terminal of the smoothing capacitor 4 is connected to a negative electrode of the DC power source 2, which is a low potential side electrode of the DC power source 2. The inverter 5 converts the input DC power into a three-phase AC having a predetermined frequency, and outputs the three-phase AC to the motor generator 3. The inverter 5 converts the AC power generated by the motor generator 3 into a DC power. The inverter 5 corresponds to a DC-AC converter.

The inverter 5 includes upper-lower arm circuits 6 for three phases. In the upper-lower arm circuit 6 of each phase, two arms are connected in series between a high potential power source line 7 and a low potential power source line 8. The high potential power source line 7 is a power source line on a positive electrode side, and the low potential power source line 8 is a power source line on a negative electrode side. In the upper-lower arm circuit 6 of each phase, a connection point between the upper arm and the lower arm is connected to an output line 9 to the motor generator 3.

In this embodiment, an n-channel type insulated gate bipolar transistor 6i (hereinafter referred to as an IGBT 6i) is adopted as a switching element constituting each arm. FWDs 6d as freewheel diodes are connected in reverse parallel to each IGBT 6i. The upper-lower arm circuit 6 for one phase is configured to have two IGBTs 6i. In the upper arm, collector electrodes of the IGBTs 6i are electrically connected to the high potential power source line 7. In the lower arm, emitter electrodes of the IGBTs 6i are electrically connected to the low potential power source line 8. The emitter electrodes of the IGBTs 6i in the upper arm and the collector electrodes of the IGBTs 6i in the lower arm are connected to each other.

In addition to the smoothing capacitor 4 and the inverter 5 described above, the electric power conversion device 1 may include a converter which is a power converter different from the inverter 5, a drive circuit for the switching element constituting the inverter 5 and the converter, and the like. The converter is a DC-DC converter that converts a DC voltage into another DC voltage having a different value.

### (Schematic Configuration of Semiconductor Device)

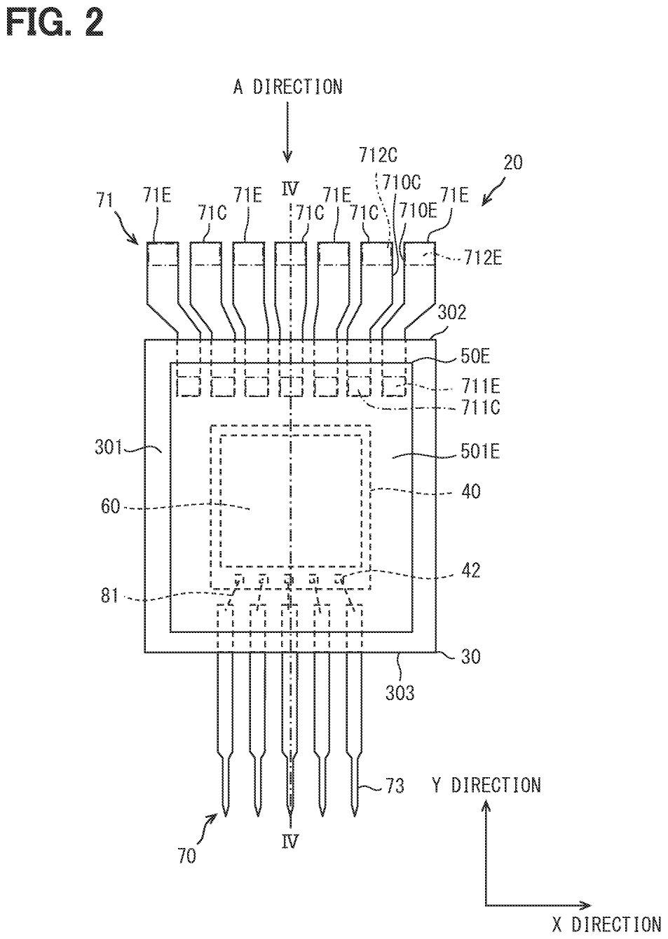

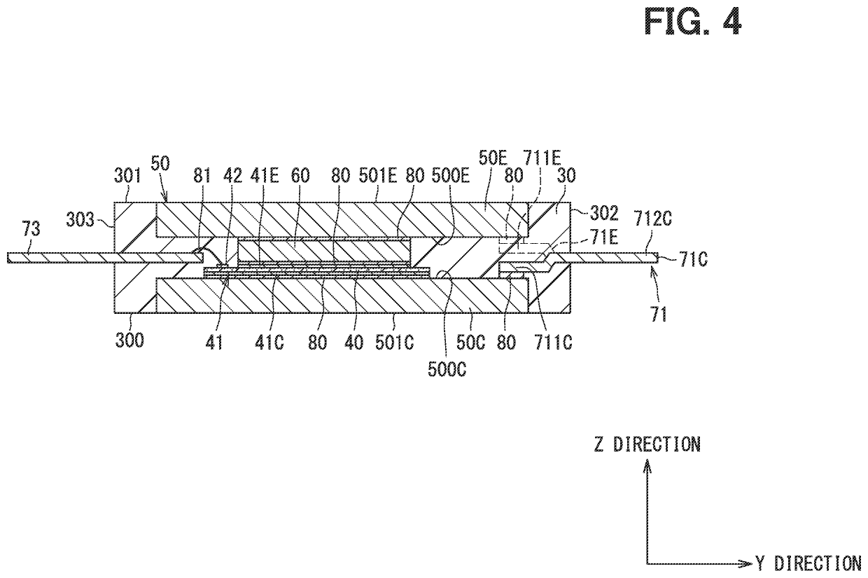

A schematic configuration of a semiconductor device 20 will be described first with reference to FIGS. 2 to 4. As shown in FIGS. 2 to 4, the semiconductor device 20 includes a sealing resin body 30, a semiconductor element 40, a heat sink 50, a terminal 60, and a lead frame 70 including a main terminal 71 and a signal terminal 73. FIG. 4 also shows a main terminal 71E for convenience.

The sealing resin body 30 seals a part of other elements constituting the semiconductor device 20. The other elements are exposed to the outside of the sealing resin body 30. The sealing resin body 30 seals, for example, the semiconductor element 40. The sealing resin body 30 seals a connection portion formed between other elements constituting the semiconductor device 20. For example, the sealing resin body 30 seals the connection portion between the semiconductor element 40 and the heat sink 50. The sealing resin body 30 seals the connection portion between the semiconductor element 40 and the terminal 60. The sealing resin body 30 seals the connection portion between the terminal 60 and the heat sink 50. The sealing resin body 30 seals the connection portion between the heat sink 50 and the main terminal 71.

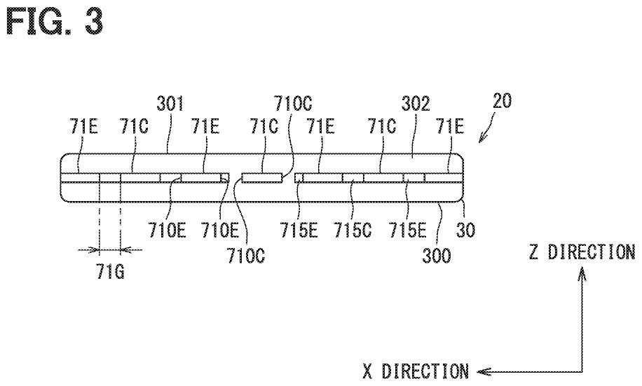

The sealing resin body 30 is made of, for example, an epoxy resin. The sealing resin body 30 is formed by, for example, a transfer molding method. The sealing resin body 30 may be referred to as a mold resin. As shown in FIGS. 2 to 3, the sealing resin body 30 has one surface 300 and a back surface 301 opposite to the one surface 300 in the Z direction. The one surface 300 and the back surface 301 are, for example, flat surfaces.

The sealing resin body 30 has a lateral surface connecting the one surface 300 and the back surface 301. As shown in FIG. 2, the sealing resin body 30 of the present embodiment has a substantially rectangular shape in a plane. The sealing resin body 30 has a side surface 302 on which the main terminal 71 protrudes to the outside and a side surface 303 on which the signal terminal 73 protrudes to the outside. The side surface 303 is a surface opposite to the side surface 302 in the Y direction.

In the semiconductor element 40, the element is formed on a semiconductor substrate such as Si, SiC, or GaN. The semiconductor device 20 includes at least one semiconductor element 40. The semiconductor element 40 includes a gate electrode and a main electrode 41 through which a main current flows. The semiconductor element 40 constitutes one of the above-described arms. The semiconductor element 40 is sometimes referred to as a semiconductor chip.

In the present embodiment, the above-mentioned IGBT 6i and FWD 6d are formed on the semiconductor substrate. As described above, RC (Reverse Conducting)—IGBT is adopted as the semiconductor element 40. Further, the element formed on the semiconductor substrate has a vertical structure so that the main current flows in the Z direction. Although not shown, the gate electrode has, for example, a trench structure. As shown in FIG. 4, the semiconductor element 40 has main electrodes on both sides thereof in the thickness direction, that is, in the Z direction.

Specifically, as the main electrode 41, a collector electrode 41C is provided on one surface side, and an emitter electrode 41E is provided on a back surface side opposite to the one surface. The collector electrode 41C also serves as a cathode electrode of the FWD 6d. The emitter electrode 41E also serves as an anode electrode of the FWD 6d. The collector electrode 41C is formed on almost the entire surface of the one side. The emitter electrode 41E is formed on a part of the back surface. The collector electrode 41C corresponds to a first main electrode, and the emitter electrode 41E corresponds to a second main electrode.

As shown in FIG. 2 and FIG. 4, the semiconductor element 40 has a pad 42, which is an electrode for signals, on the forming surface of the emitter electrode 41E. The pad 42 is formed at a position different from that of the emitter electrode 41E. The pad 42 is electrically isolated from the emitter electrode 41E. The semiconductor element 40 has a substantially rectangular shape in a plane. The pad 42 is formed at an end on the side opposite to the formation region of the emitter electrode 41E in the Y direction.

The semiconductor element 40 has, for example, five pads 42. Specifically, the pad 42 has a gate electrode pad, a potential detection pad of the emitter electrode 41E, a current sense pad, and a temperature detection pad of the semiconductor element 40. The pad 42 for temperature detection includes an anode potential pad of a temperature sensing diode, which is a temperature detecting element, and a cathode potential pad. The five pads 42 are formed side by side in the X direction.

In the semiconductor element 40, for example, an Al-based material can be used as the constituent material of the electrodes such as the main electrode 41 and the pad 42. When jointing by solder or the like, it may be preferable to include Cu as a material. For example, AlCuSi can be used.

The heat sink 50 is arranged so as to sandwich the semiconductor element 40 in the Z direction. The heat sink 50 functions at least to radiate (dissipate) the heat generated by the semiconductor element 40. Therefore, the heat sink 50 may be referred to as a heat radiating member. The heat sink 50 of the present embodiment also functions as wiring for electrically connecting the semiconductor element 40 and the main terminal 71. The heat sink 50 constitutes the main circuit of the inverter 5. Therefore, the heat sink 50 may be referred to as a wiring member.

As the heat sink 50, for example, a metal plate, a composite material of an electric insulator such as resin or ceramics and a metal body can be adopted. The same type of materials may be used for the heat sink 50C and the heat sink 50E, or different materials may be used. In this embodiment, the heat sink 50 is formed by using a metal plate including Cu.

The heat sinks 50 are provided in pairs so as to sandwich the semiconductor element 40. The semiconductor device 20 has, as the pair of heat sinks 50, a heat sink 50C placed close to the collector electrode 41C and a heat sink 50E placed close to the emitter electrode 41E. The heat sink 50 corresponds to a heat radiating member. The heat sink 50C corresponds to a first heat radiating member, and the heat sink 50E corresponds to a second heat radiating member.

The heat sinks 50C and 50E are provided so as to accommodate the semiconductor element 40 inside in a plan view from the Z direction. The heat sink 50C has a mounting surface 500C close to the semiconductor element 40 and a heat radiating surface 501C opposite to a mounting surface 500C in the Z direction. Similarly, the heat sink 50E has a mounting surface 500E and a heat radiating surface 501E. The mounting surfaces 500C and 500E face each other in the Z direction. The mounting surfaces 500C and 500E are substantially parallel to each other. In the present embodiment, the heat sinks 50C and 50E have a substantially rectangular shape in a plan view. The heat sinks 50C and 50E have substantially the same shape and size as each other. The heat sinks 50C and 50E are arranged so as to substantially coincide with each other in a plan view from the Z direction.

At least a part of each of the heat sinks 50C and 50E is sealed by the sealing resin body 30. In this embodiment, the heat radiating surface 501C of the heat sink 50C is exposed from the sealing resin body 30. The heat radiating surface 501C is substantially flush with the one surface 300. The portion of the surface of the heat sink 50C other than the connection portion with the collector electrode 41C, the heat radiating surface 501C, and the connection portion with the corresponding main terminal 71C is covered with the sealing resin body 30.

Similarly, the heat radiating surface 501E of the heat sink 50E is exposed from the sealing resin body 30. The heat radiating surface 501E is substantially flush with the back surface 301. The portion of the surface of the heat sink 50E other than the connection portion with the terminal 60, the heat radiating surface 501E, and the connection portion with the corresponding main terminal 71E is covered with the sealing resin body 30.

A collector electrode 41C of the semiconductor element 40 is connected to the mounting surface 500C of the heat sink 50C via a bonding member 80. A terminal 60 is connected to the mounting surface 500E of the heat sink 50E via a bonding member 80. As the bonding member 80, a conductive paste containing solder, Ag, or the like can be used. In this embodiment, solder is used as the bonding member 80.

The terminal 60 functions as a wiring for electrically connecting the emitter electrode 41E and the heat sink 50E. The terminal 60 functions to radiate the heat generated by the semiconductor element 40. The terminal 60 is formed by using a material having excellent conductivity and thermal conductivity, for example, a metal material such as Cu. The terminal 60 is provided so as to substantially coincide with the emitter electrode 41E in a plan view in the Z direction. The terminal 60 has a substantially rectangular parallelepiped shape. In the terminal 60, the emitter electrode 41E of the semiconductor element 40 is connected to the surface opposite to the connection surface with the heat sink 50E via the bonding member 80.

The lead frame 70 has a main terminal 71 and a signal terminal 73 as external connection terminals. The lead frame 70 is configured as a member different from the heat sink 50. The lead frame 70 is formed by processing a metal plate made of Cu or the like by a press or the like.

The main terminal 71 is an external connection terminal through which the main current flows. The lead frame 70 has multiple main terminals 71. The main terminal 71 is electrically connected to the corresponding main electrode of the semiconductor element 40. The semiconductor device 20 includes, as the main terminals 71, a main terminal 71C corresponding to the collector electrode 41C and a main terminal 71E corresponding to the emitter electrode 41E. The main terminal 71C corresponds to a first main terminal, and the main terminal 71E corresponds to a second main terminal. The main terminal 71C may be referred to as a collector terminal. The main terminal 71E may be referred to as an emitter terminal.

Each of the main terminals 71 extends inside and outside the sealing resin body 30. The main terminal 71 extends from the inside of the sealing resin body 30 in the Y direction and in a direction away from the semiconductor element 40. All the main terminals 71 project outward from the side surface 302 of the sealing resin body 30. At least the protruding portion of the main terminal 71 is arranged in the X direction. Details of the main terminal 71 will be described later.

The signal terminal 73 is connected to the pad 42 of the corresponding semiconductor element 40. The lead frame 70 has multiple signal terminals 73. The signal terminal 73 is connected to the pad 42 inside the sealing resin body 30. The five signal terminals 73 connected to the pads 42 extend in the Y direction and away from the semiconductor element 40, respectively. The signal terminals 73 are arranged in the X direction. All the signal terminals 73 project outward from the side surface 303 of the sealing resin body 30. The signal terminal 73 of the present embodiment is connected to the pad 42 via the bonding wire 81. The bonding member 80 may be used instead of the bonding wire 81.

In the semiconductor device 20 configured as described above, the sealing resin body 30 integrally seals a part of each of the semiconductor element 40 and the heat sink 50, a part of the terminal 60 and the main terminal 71, and a part of the signal terminal 73. That is, elements configuring one arm are sealed. Such a semiconductor device 20 may be referred to as a one-in-one package.

### (Main Terminal)

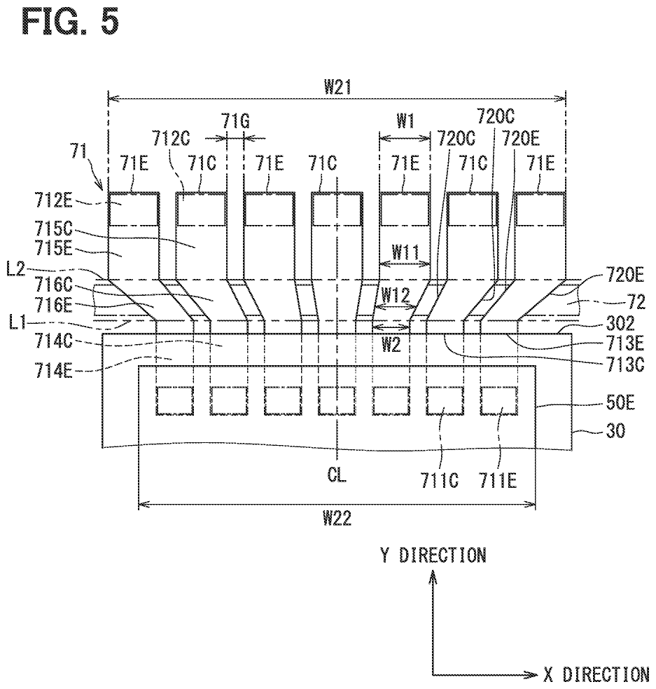

Next, the main terminal 71 of the semiconductor device 20 and its peripheral structure will be described with reference to FIGS. 2 to 5. In FIG. 5, the tie bar 72 is shown by a reference line for convenience.

As shown in FIG. 4, the main terminal 71 is connected to the corresponding heat sink 50. In the main terminal 71, the connection portion with the heat sink 50 is sealed by the sealing resin body 30. The semiconductor device 20 includes at least the multiple main terminals 71C or the multiple main terminals 71E. The semiconductor device 20 includes three or more main terminals 71.

As shown in FIGS. 2, 4 and 5, the main terminals 71C and 71E are arranged alternately in the X direction, which is the alignment direction. Alternate means that the main terminals 71C and the main terminals 71E are adjacent to each other in the arrangement direction. In the adjacent main terminals 71C and 71E, the side surfaces 710C and 710E face each other. The main terminals 71C and 71E are arranged so that the side surfaces 710C and 710E face each other, not the plate surfaces facing each other. As shown in FIG. 3, the semiconductor device 20 has multiple of sets of facing side surfaces 710C and 710E.

Adjacent main terminals 71C and 71E face each other in a part of the total length thereof. Adjacent main terminals 71C and 71E face each other in at least a part in the plate thickness direction. For example, the side surfaces may be placed so as to shift in the plate thickness direction. Preferably, one of the side surfaces 710C and 710E facing each other is placed to face the other one over the entire area in the thickness direction.

The minimum alternating configuration is a combination of two main terminals 71C and one main terminal 71E, or a combination of one main terminal 71C and two main terminals 71E. For example, in the case of two main terminals 71C and one main terminal 71E, the main terminal 71C, the main terminal 71E, and the main terminal 71C are arranged in the arrangement direction in this order. In this case, two sets of side surfaces 710C and 710E facing each other are formed.

In this embodiment, the semiconductor device 20 includes seven main terminals 71. The semiconductor device 20 includes three main terminals 71C and four main terminals 71E. The semiconductor device 20 has eight sets of facing side surfaces 710C and 710E. The plate thickness of the main terminal 71 is made to be substantially uniform over the total length. The plate thickness of the main terminal 71C and the plate thickness of the main terminal 71E are substantially equal to each other. The protruding portion of the main terminal 71 is arranged at substantially the same position in the Z direction. In the protruding portion, the adjacent main terminals 71C and 71E face each other in almost the entire thickness direction.

As shown in FIG. 4, the main terminal 71 has a bent portion in the sealing resin body 30. Adjacent main terminals 71C and 71E face each other at a portion distant from the semiconductor element 40 than the bent portion. The main terminals 71C and 71E project from the sealing resin body 30 at positions between the mounting surfaces 500C and 500E in the Z direction. Each of the main terminals 71C and 71E has a crank shape in the YZ plane.

As shown in FIG. 5, the main terminal 71C has an internal connection portion 711C, an external connection portion 712C, a boundary portion 713C, a narrowing portion 714C, a widening portion 715C, and a connecting portion 716C. Similarly, the main terminal 71E has an internal connection portion 711E, an external connection portion 712E, a boundary portion 713E, a narrowing portion 714E, a widening portion 715E, and a connecting portion 716E.

The internal connection portions 711C and 711E and the external connection portions 712C and 712E are terminal portions to which other members are connected in the main terminals 71C and 71E. The internal connection portions 711C and 711E are connection portions provided in the sealing resin body 30. The internal connection portions 711C and 711E are connected to the corresponding heat sinks 50C and 50E. The external connection portions 712C and 712E are connection portions provided outside the sealing resin body 30. Elements other than the elements constituting the semiconductor device 20, that is, other members are connected to the external connection portions 712C and 712E.

For example, when the semiconductor device 20 constitutes the upper arm, a bus bar constituting the high potential power source line 7 is connected to the external connection portion 712C, and a bus bar constituting the output line 9 is connected to the external connection portion 712E. When the semiconductor device 20 constitutes the lower arm, a bus bar constituting the output line 9 is connected to the external connection portion 712C, and a bus bar constituting the low potential power source line 8 is connected to the external connection portion 712E.

In the present embodiment, the internal connection portions 711C and 711E are provided at one end of the main terminals 71C and 71E, and the external connection portions 712C and 712E are provided at the other end in the extension direction. As shown in FIG. 4, the internal connection portion 711C is connected to the mounting surface 500C of the heat sink 50C via the bonding member 80. The internal connection portion 711E is connected to the mounting surface 500E of the heat sink 50E via the bonding member 80. The internal connection portions 711C and 711E are connected to the heat sinks 50C and 50E near the end opposite to the signal terminal 73.

The boundary portions 713C and 713E are boundary portions of the main terminals 71C and 71E between the portions protruding from the side surface 302 to the outside of the sealing resin body 30 and the portions covered with the sealing resin body 30. The boundary portions 713C and 713E are also referred to as root portions of the protruding portions. The boundary portions 713C and 713E are provided between the internal connection portions 711C and 711E and the external connection portions 712C and 712E.

As shown in FIG. 5, in the main terminals 71C and 71E, width of each of the external connection portions 712C and 712E is defined as W1, and width of each of the boundary portions 713C and 713E is defined as W2. In FIG. 5, the widths W1 and W2 are shown for one main terminal 71E. The widths W1 and W2 are the lengths of different portions in one main terminal 71. The width is a length along the X direction, which is the alignment direction, in the main terminal 71. In each of the main terminals 71C, the width W1 of the external connection portion 712C is greater than the width W2 of the boundary portion 713C. In each of the main terminals 71E, the width W1 of the external connection portion 712E is greater than the width W2 of the boundary portion 713E. Further, in all the main terminals 71, the widths W1 of the external connection portions 712C and 712E are substantially equal to each other. In all the main terminals 71, the widths W2 of the boundary portions 713C and 713E are substantially equal to each other.

The narrowing portions 714C and 714E and the widening portions 715C and 715E are portions of the main terminals 71C and 71E extending in a direction orthogonal to the alignment direction, that is, in the Y direction. In each of the main terminals 71C, the narrowing portion 714C has the boundary portion 713C and is a portion extending inside and outside the sealing resin body 30. Similarly, in each of the main terminals 71E, the narrowing portion 714E has the boundary portion 713E and is a portion extending inside and outside the sealing resin body 30. In each of the main terminals 71C, the widening portion 715C has the external connection portion 712C and is wider than the narrowing portion 714C. In each of the main terminals 71E, the widening portion 715E has the external connection portion 712E and is wider than the narrowing portion 714E. The external connection portions 712C and 712E are provided at one end of the widening portions 715C and 715E.

In this embodiment, the narrowing portions 714C and 714E include the corresponding internal connection portions 711C and 711E. The internal connection portions 711C and 711E are provided at one end of the narrowing portions 714C and 714E. Therefore, the width of each of the narrowing portions 714C and 714E is defined as the above-mentioned width W2, and the width of each of the widening portions 715C and 715E is the above-mentioned width W1. The narrowing portions 714C and 714E are extended with the width W2. The widening portions 715C and 715E are extended with the width W1. Further, in all the main terminals 71, the widths W1 of the widening portions 715C and 715E are substantially equal to each other. In all the main terminals 71, the widths W2 of the narrowing portions 714C and 714E are substantially equal to each other.

One end of the connecting portion 716C is connected to the narrowing portion 714C, and the other end is connected to the widening portion 715C. Similarly, one end of the connecting portion 716E is connected to the narrowing portion 714E, and the other end is connected to the widening portion 715E. The connecting portions 716C and 716E connect the corresponding narrowing portions 714C and 714E and the widening portions 715C and 715E. Each of the connecting portions 716C and 716E includes a portion wider than each of the boundary portions 713C and 713E. In an extending portion from each of the boundary portions 713C and 713E of the main terminals 71 to each of the external connection portions 712C and 712E, width W11 of an arbitrary first position is set to be equal to or greater than width W12 of an arbitrary second position. The second position is a position closer to the side surface 302 of the sealing resin body 30 than the first position. In FIG. 5, the widths W11 and W12 are shown in one main terminal 71E.

In the present embodiment, the width of each of the connecting portions 716C and 716E increases toward the direction approaching the widening portions 715C and 715E. The width of each of the connecting portions 716C and 716E gradually increases toward the direction from each of the narrowing portions 714C and 714E to each of the widening portions 715C and 715E. In the connecting portions 716C and 716E, the width W11 is greater than the width W12.

The gap 71G between the adjacent main terminals 71C and 71E is set to be substantially constant over the total length of the facing region. In the adjacent main terminals 71C and 71E, the gap 71G between the boundary portions 713C and 713E and the gap 71G between the external connection portions 712C and 712E are substantially equal to each other. The gap 71G is set to a predetermined interval capable of securing electrical insulation between the main terminals 71C and 71E. The gap 71G is constant at the multiple main terminals 71.

For this reason, the inclination angle of each of the connecting portions 716C and 716E with respect to the Y direction increases as the distance from the center of the main terminals 71 increases in the arrangement direction. In other words, the farther away from the center, the greater the deviation of the position of each of the corresponding narrowing portions 714C and 714E and each of the corresponding widening portions 715C and 715E in the X direction. The deviation of the position in the X direction is the deviation of the center position of the width. The inclination angle represents an angle formed by a virtual line passing through the center position of the width and a virtual line along the Y direction. The width W21 of the arrangement area of the main terminals 71 is greater than the width W22 of the heat sink 50 (metal body). The arrangement area of the main terminals 71 is an area between the outside and the outside of the main terminals 71 at both ends in the arrangement direction of the main terminals 71, and is hereinafter referred to as a terminal area. The terminal area is wider than the heat sink 50 in a portion including the external connection portions 712C and 712E. The center of the main terminal 71 described above is the center of the terminal area.

The center of the main terminal 71 substantially coincides with the center line CL passing through the element center of the semiconductor element 40.

As shown in FIG. 5, the main terminals 71C and 71E are symmetrically arranged with respect to the center line CL. The element center is the center of the semiconductor element 40 when there is one semiconductor element 40 as in the present embodiment. When there are two semiconductor elements 40, for example, it is the central position between the centers in the alignment direction of the two semiconductor elements 40. The center line CL is a virtual line orthogonal to the X direction and passing through the element center. The center line CL shown in FIG. 5 is provided at the dash-dot line position indicated by the cross section in FIG. 3.

Further, the main terminals 71C and 71E have tie bar marks 720C and 720E. The tie bar marks 720C and 720E are formed in and near the connecting portion of the tie bar 72. The tie bar marks 720C and 720E are cutting marks of the tie bar 72. The tie bar 72 is removed as an unnecessary portion of the lead frame 70 after molding the sealing resin body 30. Due to the removal of the tie bar 72, the main terminal 71C and the main terminal 71E are electrically separated in the semiconductor device 20.

As shown by a reference line in FIG. 5, the tie bar 72 is connected to the connecting portions 716C and 716E in the state before cutting. The tie bar 72 connects the connecting portions 716C and 716E to each other and fixes them to an outer peripheral frame of the lead frame 70 (not shown). One end of each of the connecting portions 716C and 716E is connected to each of the narrowing portions 714C and 714E, and the other end is connected to each of the widening portions 715C and 715E. The tie bar 72 is provided at a position closer to the other end than the one end of the connecting portions 716C and 716E, and is provided at a position closer to the one end than the other end. The tie bar 72 is provided apart from the narrowing portions 714C and 714E and the widening portions 715C and 715E.

As a result, the tie bar marks 720C and 720E are also provided at positions closer to the other end than one end of the connecting portions 716C and 716E, and are provided closer to one end than the other end. The tie bar marks 720C and 720E are provided apart from the narrowing portions 714C and 714E and the widening portions 715C and 715E.

### Summary of First Embodiment

According to the semiconductor device 20 of the present embodiment, the main terminals 71C and 71E are arranged alternately. The side surfaces 710C and 710E of the adjacent main terminals 71C and 71E face each other. The directions of the main currents of the main terminal 71C and the main terminal 71E are substantially opposite to each other. As a result, the magnetic fluxes generated when the main current flows cancel each other, and the inductance can be reduced. The side surface is smaller than the plate surface, which is the surface in the plate thickness direction, but the main terminal 71 has the multiple sets of opposite side surfaces 710C and 710E. Accordingly, it is possible to effectively reduce the inductance. Further, the multiple main terminals 71C and 71E of the same type are provided in parallel. This configuration also makes it possible to reduce the inductance.

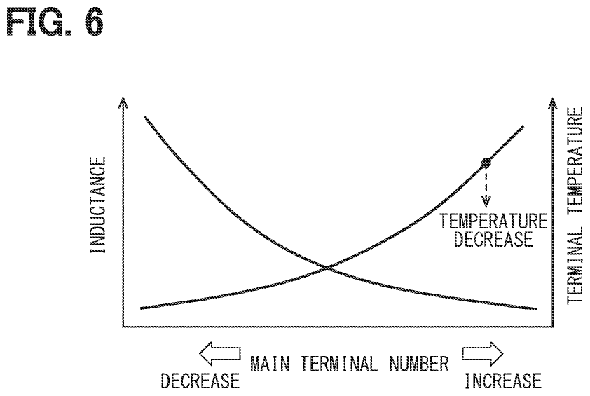

FIG. 6 shows the relationship between the total number of main terminals, the inductance, and the terminal temperature for the reference example. In the reference example, the width of the main terminal 71 is assumed to be equal over the total length. In addition, the width of the terminal area is assumed to be constant. As shown in FIG. 6, it is clear that the inductance can be reduced as the number of main terminals increases, that is, as the number of pairs of facing surfaces increases.

This embodiment has three main terminals 71C and four main terminals 71E. Accordingly, it is possible to effectively reduce the inductance. Thereby, for example, the surge voltage generated by the switching of the IGBT 6i can be reduced.

On the other hand, in the configuration in which all the main terminals are drawn out from one surface of the sealing resin body, the width of the terminal region is set to be less than the width of one surface at the boundary portion. As a comparative example, it is assumed that the main terminal has a constant width and is drawn out from the inside of the sealing resin body. In this configuration, the proportion of the gap between the terminals increases as the number of main terminals increases in order to reduce the inductance. Thus, the cross-sectional area of each of the main terminals becomes smaller, and the electrical conduction region becomes smaller at the main terminals having the same potential. Therefore, for example, it becomes difficult for a DC current to flow. Therefore, as shown in FIG. 6, as the number of main terminals increases, the temperature of the main terminals rises. The rise in terminal temperature may cause peeling of the sealing resin body, for example.

The DC current is a current (direct current) that flows in a steady state when the semiconductor element (the switching element) turns on. The AC current is a current (alternating current) that flows when the semiconductor element is switched. Most of the heat generated by the semiconductor device 20 is generated by the DC current.

On the other hand, in the present embodiment, the width W1 of each of the external connection portions 712C and 712E is greater than the width W2 of each of the boundary portions 713C and 713E. Since the electrical conduction region of the main terminal 71 is greater than that of the configuration in which the main terminals are pulled out with the same width, it is possible to suppress heat generation of the main terminal 71. It is possible to suppress heat generation mainly due to the DC current. Further, since the heat radiation area by the main terminal 71 is large outside the sealing resin body 30, the generated heat can be effectively dissipated. Therefore, it is possible to suppress the temperature rise of the main terminal 71. As shown by the broken line arrow in FIG. 6, even when the number of main terminals is the same, the terminal temperature can be lowered as compared with the reference example shown by the solid line.

As described above, according to the semiconductor device 20 of the present embodiment, it is possible to suppress the temperature rise of the main terminal 71 while reducing the inductance.

The shape of the main terminal 71 is not particularly limited. As described above, at least the condition in which the width W1 is greater than the width W2 may be satisfied. In the present embodiment, the main terminal 71 has a portion wider than the width W2 between the boundary portions 713C and 713E and the external connection portions 712C and 712E. Further, from the boundary portions 713C and 713E to the external connection portions 712C and 712E, the width W11 of the first position is set to be equal to or larger than the width W12 of the second position closer to the side surface 302 than the first position. The main terminal 71 is widened from the boundary portions 713C and 713E to the external connection portions 712C and 712E while satisfying the relationship of width W1>width W2. Therefore, the temperature rise of the main terminal 71 can be effectively suppressed.

The arrangement of the main terminal 71 with respect to the heat sink 50 is not particularly limited. In the present embodiment, the width W21 of the terminal region in the external connection portions 712C and 712E is greater than the width W22 of the heat sink 50. The width of the terminal region in the boundary portions 713C and 713E is smaller than the width W22 of the side surface 302 and the heat sink 50. In this way, the main terminal 71 is pulled out from the side surface 302 of the sealing resin body 30, and the width is widened at a position away from the side surface 302. Therefore, the temperature rise of the main terminal 71 can be suppressed more effectively. The width W21 may be substantially equal to the width W22. When the gap 71G is constant, the temperature rise of the main terminal 71 can be effectively suppressed as compared with the configuration in which the width W21<width W22 is satisfied.

In the lead frame 70, the connection position of the tie bar 72 with respect to the main terminal 71 is not particularly limited. In the present embodiment, the main terminal 71 is extended in the Y direction and has narrowing portions 714C and 714E, widening portions 715C and 715E, and connecting portions 716C and 716E having different widths from each other. In this configuration, the farther away from the center of the main terminal 71, the larger the positional deviation between the narrowing portions 714C and 714E and the widening portions 715C and 715E in the X direction. The connecting portions of the connecting portions 716C and 716E and the narrowing portions 714C and 714E and the connecting portions of the connecting portions 716C and 716E and the widening portions 715C and 715E are bent on both sides of the width.

In the present embodiment, the tie bar marks 720C and 720E are formed at positions apart from the narrowing portions 714C and 714E and the widening portions 715C and 715E in the connecting portions 716C and 716E. According to this configuration, the tie bar 72 can be cut so as not to include the bent portion. It is also possible to lengthen the narrowing portions 714C and 714E and the widening portions 715C and 715E at the protruding portion of the main terminal 71, and connect the tie bar 72 to the narrowing portions 714C and 714E and the widening portions 715C and 715E. However, the inductance increases. According to the present embodiment, the tie bar 72 can be easily removed while suppressing an increase in inductance by using the connecting portions 716C and 716E that are structurally generated.

In the present embodiment, the main terminals 71C and 71E are arranged line-symmetrically with respect to the center line CL of the semiconductor element 40. As a result, the main current flows so as to be line-symmetric with respect to the center line CL. The main current flows almost evenly on the left side and the right side with respect to the center line CL. Thereby, it may be possible to reduce the inductance. In addition, it may be possible to suppress local heat generation.

An example of having three main terminals 71C and four main terminals 71E has been shown, but the present embodiment is not limited thereto. The number of main terminals 71C may be larger than the number of main terminals 71E. For example, the number of main terminals 71C may be four and the number of main terminals 71E may be three. In this case, the main terminals 71C are arranged at both ends in the alignment direction.

An example is shown in which the signal terminal 73 is connected to the pad 42 via the bonding wire 81, but the present embodiment is not limited thereto. For example, the signal terminal 73 may be connected to the pad 42 via the bonding member 80. An example is shown in which the semiconductor device 20 includes a terminal 60, but the present embodiment is not limited thereto. It is also possible to have a configuration that does not include the terminal 60. By adopting the heat sink 50E having a convex portion on the mounting surface 500E side, it is possible to achieve a configuration that does not include the terminal 60 while adopting the bonding wire 81.

The connection position of the main terminal 71 with respect to the heat sink 50 is not limited to the above example. For example, the main terminal 71 may be connected to the side surface of the corresponding heat sink 50.

An example is shown in which the main terminal 71 and the signal terminal 73 are configured as a part of the lead frame 70, but the present embodiment is not limited thereto. At least one of the main terminals 71C and 71E may be integrally connected to the heat sinks 50C and 50E.

### Second Embodiment

This embodiment is a modification example which is based on the preceding embodiment. In the above embodiment, the widths of all the external connection portions 712C and 712E are made substantially equal to each other in the odd number of main terminals 71. Instead, the widths of the main terminals 71 at both ends may be narrower than the width of the central main terminal 71.

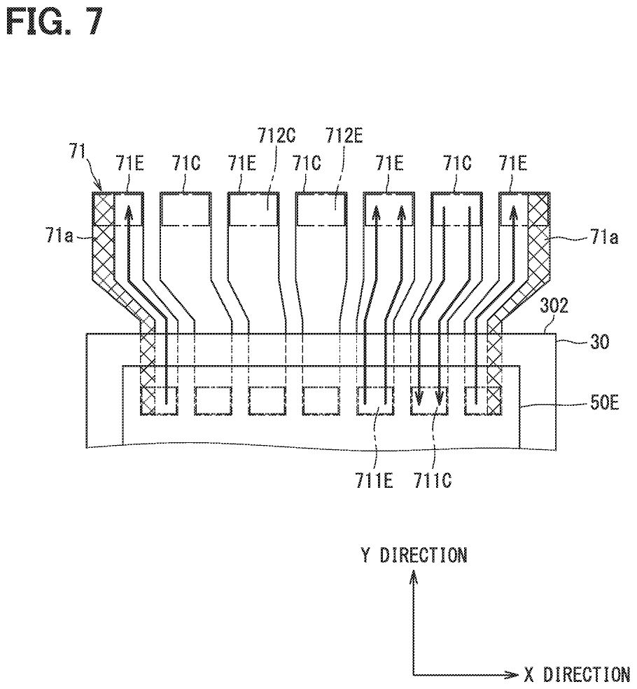

The higher the switching frequency, the greater the influence of the skin effect and the proximity effect on the current flowing during switching, that is, the AC current. In the example shown in FIG. 7, the widths of the internal connection portions 711C and 711E are substantially equal to each other. Further, the widths of the external connection portions 712C and 712E are substantially equal to each other. With respect to the main terminals 71E located at both ends, the main terminal 71C is not arranged on the outside, and the main terminal 71C is arranged only on the inside. Due to the proximity effect, the AC current flows in the area inside the main terminals 71E located at both ends. Of the main terminals 71E at both ends, almost no AC current flows in the outer region 71a. The solid line shown in FIG. 7 indicates the flow of AC current at a predetermined timing. FIG. 7 corresponds to FIG. 5.

In a configuration including an odd number of main terminals 71, the number of main terminals 71C and the number of main terminals 71E are different, so that there is a difference in the electrical conduction region. Specifically, an electrical conduction region of the main terminals of small numbers is smaller than an electrical conduction area of the main terminals of large numbers. In the configuration shown in FIG. 7, the electrical conduction region of the main terminal 71C is smaller than the electrical conduction region of the main terminal 71E.

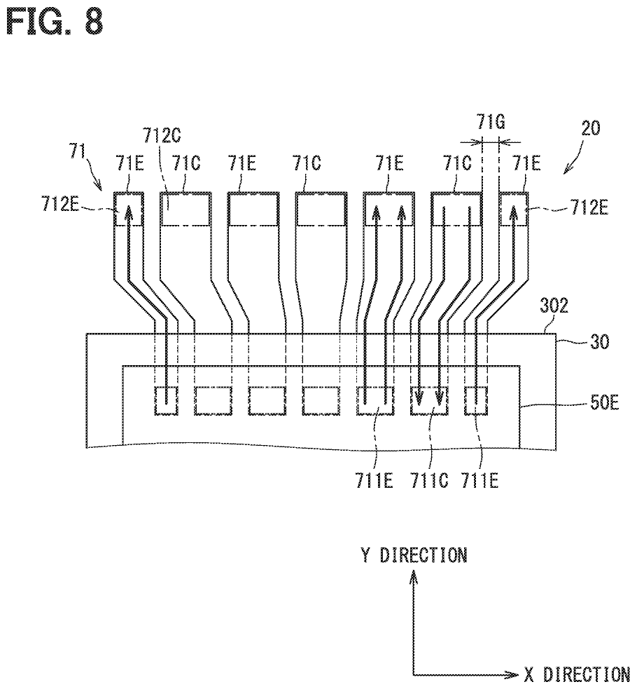

FIG. 8 shows the periphery of the main terminal 71 in the semiconductor device 20 of the present embodiment, and corresponds to FIG. 5. Similarly to FIG. 7, the semiconductor device 20 includes three main terminals 71C and four main terminals 71E. The gap 71G is substantially equalized between the terminals 71 as in the prior embodiment. The main terminals 71C and the main terminals 71E are alternately arranged through a predetermined gap. The widths of the main terminals 71E located at both ends are narrower than those in FIG. 7.

The width of each of the internal connection portions 711E at both ends is narrower than the width of each of the central internal connection portions 711C and 711E sandwiched between both ends. The width of each of the external connection portions 712E at both ends is narrower than the width of each of the central external connection portions 712C and 712E. The width of each of the main terminals 71E arranged at both ends is narrower than that of the main terminals 71E shown in FIG. 7 by the amount of the region 71a. The width of each of the main terminals 71E at both ends is narrower over the total length at the same position in the Y direction as compared with the width of each of the central main terminals 71C and 71E.

### Summary of Second Embodiment

In the present embodiment, among the main terminals 71 of odd numbers, the widths of the main terminals 71E at both ends are narrower than the widths of the central main terminals 71C and 71E. Since the inner portion through which the AC current mainly flows is left, the inductance of the main terminal 71 can be secured at the same level as the configuration in which the widths of the main terminals 71E at both ends is not narrowed. Further, since the width of each of the main terminals 71E at both ends is narrowed by the amount of the region 71a, the electrical conduction region of the main terminals 71C having a small number can be brought closer to the electrical conduction region of the main terminals 71E having a large number. As a result, the heat generated by the main terminal 71 can be brought close to each other between the main terminal 71C and the main terminal 71E. For example, it can be equalized. Although the description is omitted, the semiconductor device 20 of the present embodiment can exhibit the same effect in the portion having the same configuration as the semiconductor device 20 described in the first embodiment.

As the main terminal 71, an example having three main terminals 71C and four main terminals 71E has been shown, but the present embodiment is not limited thereto. The number of main terminals 71C may be larger than the number of main terminals 71E. When the number of main terminals 71 is an odd number of 3 or more, the configuration shown in this embodiment can be applied. The odd number of main terminals 71 is equivalent to having an even number of side surfaces 710C and 710E facing each other.

### Third Embodiment

This embodiment is a modification example which is based on the preceding embodiment. In the above embodiment, the number of main terminals 71 is an odd number. Instead of this configuration, the number of main terminals 71 may be an even number.

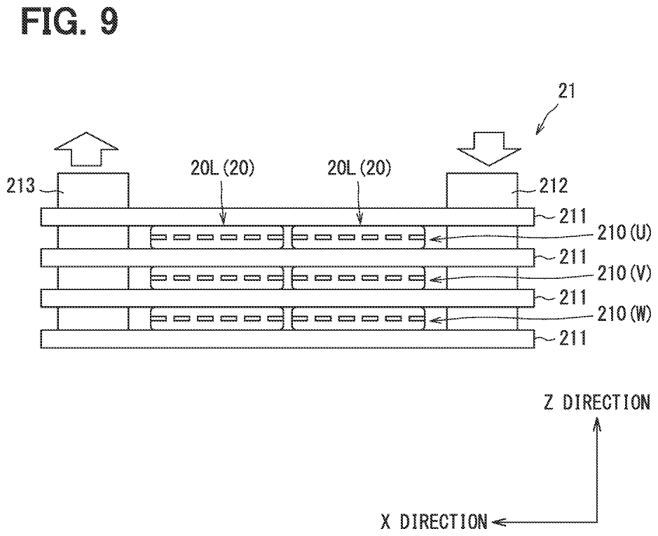

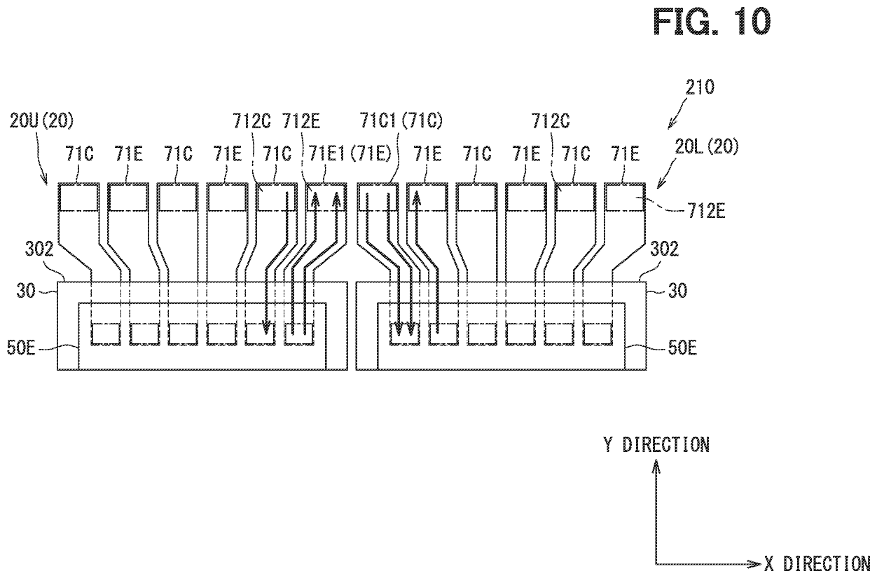

As shown in FIGS. 9 and 10, the semiconductor device 20 of the present embodiment includes an even number of main terminals 71. FIG. 9 shows a stacking body 21. The stacking body 21 includes a semiconductor module 210 and a cooler 211.

The semiconductor module 210 includes two semiconductor devices 20 that form a one-phase upper and lower arm circuit 6. In the following, among the upper and lower arm circuits 6, the semiconductor device 20 constituting the upper arm may be referred to as a semiconductor device 20U. The semiconductor device 20 constituting the lower arm may be referred to as a semiconductor device 20L. The stacking body 21 includes a semiconductor module 210 for three phases. The stacking body 21 includes a semiconductor module 210 (U), a semiconductor module 210 (V), and a semiconductor module 210 (W). The semiconductor module 210 (U) constitutes an upper and lower arm circuit 6 of a U-phase. The semiconductor module 210 (V) constitutes an upper and lower arm circuit 6 of a V-phase. The semiconductor module 210 (W) constitutes an upper and lower arm circuit 6 of a W-phase. The stacking body 21 includes six semiconductor devices 20.

The semiconductor module 210 and the cooler 211 are arranged alternately in the Z direction. Each of the semiconductor modules 210 is sandwiched by the cooler 211. The semiconductor devices 20U and 20L constituting one semiconductor module 210 are arranged in the X direction. The semiconductor devices 20U and 20L are arranged so that, for example, a heat radiating surface 501C faces the same cooler 211. Each of the semiconductor devices 20U and 20L includes multiple main terminals 71 of three or more. For example, each of the semiconductor devices 20U and 20L includes six main terminals 71. That is, each of the semiconductor devices 20U and 20L includes three main terminals 71C and three main terminals 71E. Each of the semiconductor devices 20U and 20L has the same configuration as that of the preceding embodiment (see FIG. 5) except that the number of main terminals 71 is an even number. The main terminals 71 of the semiconductor devices 20U and 20L are drawn out to the same side in the Y direction.

The cooler 211 may be referred to as a heat exchange unit. Inside the cooler 211, a flow path through which the refrigerant flows is formed. A refrigerant introduction pipe 212 and a refrigerant discharge pipe 213 are connected to the cooler 211. The refrigerant introduction pipe 212 and the refrigerant discharge pipe 213 are tubular members each having a flow path formed therein. The refrigerant introduction pipe 212 and the refrigerant discharge pipe 213 extend in the Z direction. In each of the coolers 211, the refrigerant introduction pipe 212 is connected to one end side in the X direction, and the refrigerant discharge pipe 213 is connected to the other end side. The flow path of the cooler 211 and the flow paths of the refrigerant introduction pipe 212 and the refrigerant discharge pipe 213 are integrally connected. The refrigerant introduced from the refrigerant introduction pipe 212 flows through the flow paths of each of the coolers 211 and is discharged to the outside from the refrigerant discharge pipe 213.

As the refrigerant, a phase transition refrigerant such as water or ammonia, or a non-phase transition refrigerant such as ethylene glycol can be used. The coolers 211 mainly cool the semiconductor devices 20. However, in addition to the cooling function, the cooler 120 may have a warming function when the environmental temperature is low. Then, the cooler 211 may be referred to as the temperature adjusting instrument. The refrigerant is referred to as a heat medium.

### Summary of Third Embodiment

In the present embodiment, the semiconductor devices 20U and 20L constituting the semiconductor module 210 are arranged in the X direction with the main terminal 71 drawn out in the same direction. Due to this arrangement, as shown in FIG. 10, the main terminal 71E located at the end of the semiconductor device 20U and the main terminal 71C located at the end of the semiconductor device 20L are adjacent to each other in the X direction. In the following, the main terminals 71C and 71E located at the ends and adjacent to each other are referred to as main terminals 71C1 and 71E1. Further, since the widths of the external connection portions 712C and 712E are wide, the main terminals 71C1 and 71E1 are close to each other.

Therefore, due to the proximity effect, the AC current also flows in the portion of the main terminal 71E1 close to the main terminal 71C1, that is, the outer portion. Similarly, due to the proximity effect, the AC current also flows in the portion of the main terminal 71C1 close to the main terminal 71E1, that is, the outer portion. As one semiconductor module 210, the inductance can be further reduced. Although the description is omitted, the semiconductor device 20 of the present embodiment can exhibit the same effect in the portion having the same configuration as the semiconductor device 20 described in the first embodiment.

As the main terminal 71, an example having three main terminals 71C and three main terminals 71E has been shown, but the present embodiment is not limited thereto. The even number of main terminals 71 is equivalent to having an odd number of side surfaces 710C and 710E facing each other.

### Fourth Embodiment

This embodiment is a modification example which is based on the preceding embodiment. In the above embodiment, the main terminal 71E is connected to the emitter electrode 41E via the heat sink 50E. Alternatively, the main terminal 71E may be connected to the emitter electrode 41E without passing through the heat sink 50E.

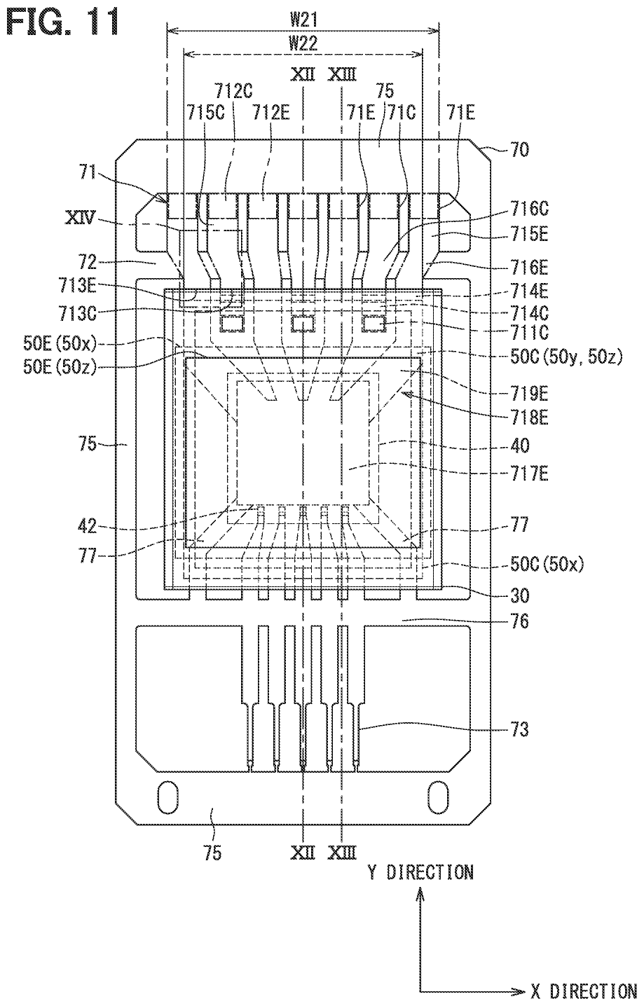

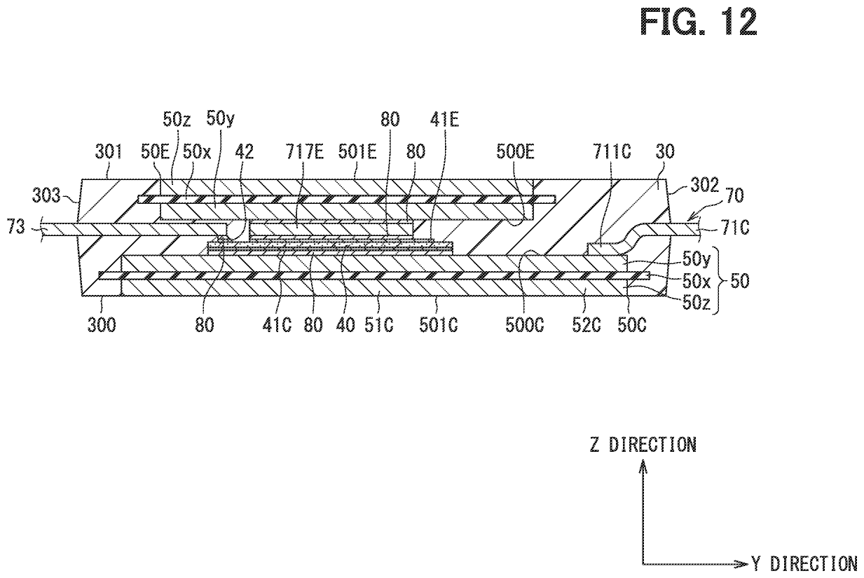

As shown in FIGS. 11 to 13, the semiconductor device 20 of the present embodiment does not include the terminal 60, unlike the preceding embodiments. FIG. 11 shows the state before the tie bar cut for convenience. The main terminal 71E constituting the lead frame 70 is connected to the emitter electrode 41E via a bonding member 80. The heat sink 50E is connected to the main terminal 71E via the bonding member 80. As shown in FIG. 12, the signal terminal 73 is also connected to the pad 42 via the bonding member 80.

In the present embodiment, the heat sinks 50 has a substantially rectangular shape in a plan view. The length of the heat sink 50E in the X direction is slightly longer than that of the heat sink 50C. The length of the heat sink 50C in the Y direction is longer than that of the heat sink 50E. The heat sink 50C straddles the heat sink 50E in the Y direction. The heat sink 50C crosses the heat sink 50E. The heat sink 50C has a facing portion 51C and a non-facing portion 52C. The facing portion 51C is a portion facing the mounting surface 500E of the heat sink 50E in the Z direction, and the facing portion 51C is a portion overlapping the mounting surface 500E in a plan view from the Z direction. The non-facing portion 52C is continuous from the facing portion 51C at a position close to the main terminal 71 in the Y direction. The non-facing portion 52E faces a portion facing the heat sink 50E.

In this embodiment, a Direct Bonded Copper (DBC) substrate is used as the heat sink 50. The heat sink 50 has an insulator 50x and metal bodies 50y and 50z arranged so as to sandwich the insulator 50x. The insulator 50x is a substrate made of resin, ceramics, or the like. The metal bodies 50y and 50z are formed by material including, for example, Cu. The metal bodies 50y and 50z are directly bonded to the insulator 50x. The heat sink 50 is stacked in the order of the metal body 50y, the insulator 50x, and the metal body 50z from the side of the semiconductor element 40. The heat sink 50 has a three-layer structure.

The planar shapes and sizes of the metal bodies 50y and 50z are substantially same as each other. The planar shape of the insulator 50x, which is the intermediate layer, is similar to that of the metal bodies 50y and 50z. The size of the insulator 50x is larger than that of the metal bodies 50y and 50z. The insulator 50x extends to the outside of the metal bodies 50y and 50z all around. In the heat sinks 50C and 50E, one surface of the metal body 50y forms the mounting surfaces 500C and 500E. In the heat sinks 50C and 50E, one surface of the metal body 50z forms the heat radiating surfaces 501C and 501E.

The collector electrode 41C is connected to the facing portion 51C of the heat sink 50 via the bonding member 80. The collector electrode 41C is connected to the metal body 50y of the heat sink 50C in the facing portion 51C. The main terminal 71C is connected to the metal body 50y of the heat sink 50C in the non-facing portion 52C. The main terminal 71C may be connected to the heat sink 50C via the bonding member 80. The main terminal 71C is directly connected to the heat sink 50C by ultrasonic bonding, friction stir welding, laser welding or the like.

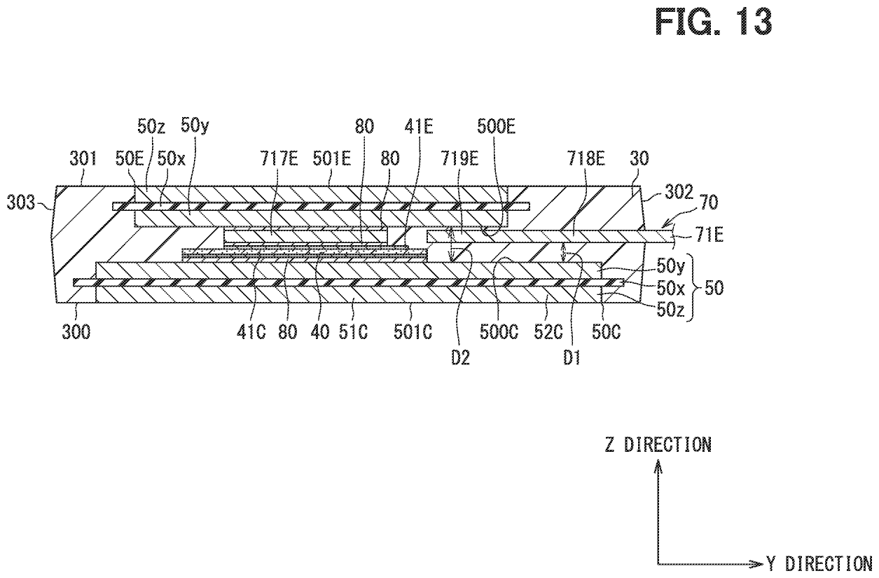

As shown in FIGS. 11 and 13, the main terminal 71E has an electrode connection portion 717E and an extending portion 718E. The main terminal 71E has an electrode connection portion 717E instead of the internal connecting portion 711E connected to the heat sink 50E. The electrode connection portion 717E is also a connecting portion formed inside the sealing resin body 30. The electrode connection portion 717E is a connection portion of the main terminal 71E to the emitter electrode 41E. The electrode connection portion 717E is connected to the emitter electrode 41E via the bonding member 80. The electrode connection portion 717E is a portion overlapping with the emitter electrode 41E in the plan view from the Z direction. The main terminal 71E includes the electrode connection portion 717E and is connected to the heat sink 50E. In the electrode connection portion 717E, the bonding member 80 is arranged on both the plate surfaces.

The extending portion 718E is a portion extending from the electrode connection portion 717E. The extending portion 718E is integrally connected to the electrode connection portion 717E. The extending portion 718E includes an external connection portion 712E and a boundary portion 713E as in the previous embodiment. Further, the narrowing portion 714E, the widening portion 715E, and the connecting portion 716E are included. The extending portion 718E further includes a connecting portion 719E.

The narrowing portion 714E includes a boundary portion 713E. The end portion of the narrowing portion 714E in the sealing resin body 30 is not connected to the heat sink 50E. That is, the narrowing portion 714E does not include the internal connection portion 711E. The connecting portion 719E is connected to one end of the narrowing portion 714E. The connecting portion 719E is a portion of the extending portion 718E from the boundary with the electrode connection portion 717E to the narrowing portion 714E. As described above, the extending portion 718E has the connecting portion 719E, the narrowing portion 714E including the boundary portion 713E, the connecting portion 716E, and the widening portion 715E including the external connection portion 712E from the electrode connection portion 717E side.

A part of the extending portion 718E faces the mounting surface 500C of the heat sink 50C at a position closer to the mounting surface 500E. In each of the extending portions 718E, at least a part of the connecting portion 719E and a part of the narrowing portion 714E face the mounting surface 500C. The extending portion 718E has a portion facing the facing portion 51C of the heat sink 50 and a portion facing the non-facing portion 52C. As shown in FIG. 13, the facing distance D1 between the extending portion 718E of the main terminal 71E and the mounting surface 500C is smaller than the facing distance D2 between the mounting surfaces 500C and 500E. The main terminal 71E of the present embodiment is extended without having a bent portion. The facing distance D1 is constant. The main terminals 71C and 71E face each other in a portion on the tip side of the bent portion of the main terminal 71C.

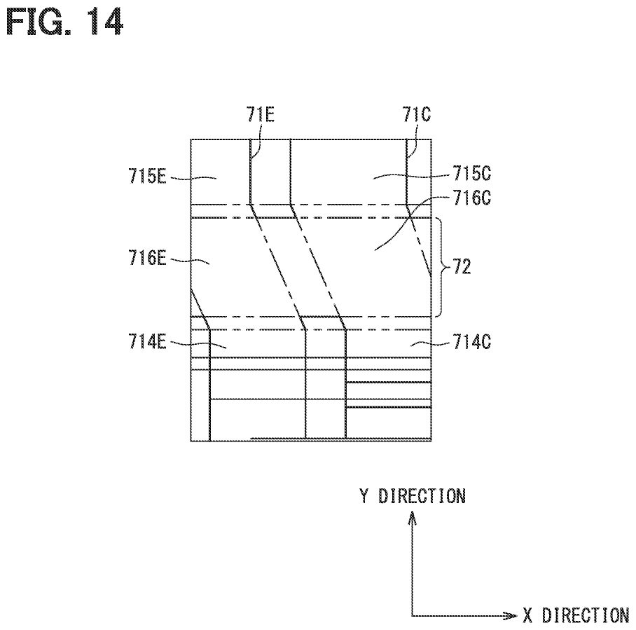

The lead frame 70 has an outer peripheral frame 75, a tie bar 76, and a suspension lead 77 in addition to the tie bar 72 shown in the preceding embodiment in a state before the tie bar cut. The outer peripheral frame 75 may be also referred to as an outer peripheral frame body. The tie bar 72 extends in the X direction, and the both ends are connected to the outer peripheral frame 75. The multiple main terminals 71C are supported by the outer peripheral frame 75 with use of the tie bar 72. As shown in FIG. 14, the tie bar 72 is connected to the connecting portions 716C and 716E. The tie bar 72 is provided apart from the narrowing portions 714C and 714E and the widening portions 715C and 715E. Therefore, the tie bar marks 720C and 720E (not shown) are provided apart from the narrowing portions 714C and 714E and the widening portions 715C and 715E as in the preceding embodiment.

The tie bar 76 is provided on the side opposite to the tie bar 72 with reference to the semiconductor element 40. The tie bar 76 extends in the X direction, and the both ends are connected to the outer peripheral frame 75. The multiple signal terminals 73 are supported by the outer peripheral frame 75 with use of the tie bar 76. One end of the suspension lead 77 is connected to the electrode connection portion 717E, and the other end is connected to the tie bar 76. Two suspension leads 77 are provided so as to sandwich the signal terminal 73 in the X direction.

The tips of the protruding portions of the main terminals 71C and 71E are connected to the outer peripheral frame 75 in the Y direction. The electrode connection portion 717E is connected to the tie bar 72 via the extending portion 718E, and is connected to the tie bar 76 via the suspension lead 77. After the molding of the sealing resin body 30, the unnecessary portion of the lead frame 70 such as the outer peripheral frame 75 and the tie bars 72 and 76 are removed. Thereby, in the semiconductor device 20, the main terminals 71C and 71E are electrically separated. Further, the multiple signal terminals 73 are electrically separated. The semiconductor device 20 does not include, as the lead frame 70, the outer peripheral frame 75 and the tie bars 72 and 76, and includes the main terminal 71, the signal terminal 73, and the suspension lead 77.

(Extending portion of Main terminal)

Next, the extending portion 718E of the main terminal 71E will be described with reference to FIG. 11. The semiconductor device 20 includes three main terminals 71C and four extending portions 718E. The four extending portions 718E extend from one electrode connection portion 717E. Outside the sealing resin body 30, the main terminal 71C and the extending portion 718E of the main terminal 71E are alternately arranged. In the present embodiment, the extending portion 718E defines the number of main terminals 71E that are alternately arranged with the main terminals 71C.

The four extending portions 718E are arranged in the X direction. From the narrowing portion 714E to the tip portion, the extending portion 718E and the main terminal 71C are alternately arranged. Also in the present embodiment, the width W21 of the terminal region in the external connection portions 712C and 712E is greater than the width W22 of the heat sink 50. In the case of the DBC substrate, the width W22 is defined by the wide side of the metal bodies 50y forming the mounting surfaces 500C and 500E. The width W21 of the terminal region is greater than the width W22 of the metal body 50y forming the mounting surface 500E.

The connecting portions 719E are arranged in the X direction without interposing the main terminal 71C between them. In the four extending portions 718E, the positions of the ends of the narrowing portions 714E are substantially the same in the Y direction. As shown in FIG. 11, in the X direction, the width of each of the connecting portions 719E arranged at both ends is greater than the width of each of the connecting portions 719E arranged at the center between both ends. The width of each of the two connecting portions 719E arranged in the center is substantially the same as the narrowing portion 714E over the total length. On the other hand, the width of each of the two connecting portions 719E arranged at the ends is greater than the width of the narrowing portion 714E over the total length. Having the great width over the total length means that a width relationship is established over the total length when the same positions are compared in the Y direction.

The four connecting portions 719E (extending portions 718E) extend radially from the electrode connection portion 717E. The electrode connection portion 717E has a substantially rectangular shape in a plane. The connecting portion 719E at the end extends from two adjacent corners of the electrode connection portion 717E. The central connecting portion 719E extends from the vicinity of the center of the side of the side surface 302. Although not shown in the center line CL, the main terminals 71C and 71E are also arranged in line symmetry with respect to the center line CL of the semiconductor element 40 in the X direction, although the illustration of the center line CL is omitted.

### Summary of Fourth Embodiment

In this embodiment, the main terminal 71E is placed between the heat sink 50E and the semiconductor element 40, and is connected to the emitter electrode 41E. As a result, as shown in FIG. 13, the main terminal 71E is closest as a portion having the same potential as the emitter electrode 41E facing the heat sink 50C. As a result, the effect of canceling the magnetic flux can be enhanced and the inductance can be reduced.

When the signal terminal 73 is connected to the pad 42 via the bonding wire 81 as shown in the prior embodiment, the wire 81 is made to be higher by increasing the plate thickness of the electrode connection portion 717E, that is, the plate thickness of the lead frame 70. The electrode connection portion 717E functions as a spacer. On the other hand, in this embodiment, the signal terminal 73 is connected to the pad 42 via a bonding member 80. As a result, the plate thickness of the electrode connection portion 717E can be reduced, so that the mounting surface 500E is closer to the mounting surface 500C. This configuration also makes it possible to reduce the inductance.

In the configuration in which the multiple extending portions 718E extend from the electrode connection portion 717E, in the arrangement direction (X direction) of the main terminals 71, the distance from the electrode connection portion 717E to the narrowing portion 714E, that is, the electrical conduction path by the connecting portion 719E becomes long as the distance from the center of the arrangement increases. Therefore, when the widths are equal to each other, the longer the extending portion 718E of the connecting portion 719E, the more difficult it is for a DC current to flow, for example.

On the other hand, in the present embodiment, the main terminal 71E has four extending portions 718E. The width of each of the connecting portions 719E at both ends is greater than the width of the connecting portion 719E at the center. The width of the connecting portion 719E having a long electrical conduction path is increased. Therefore, it is possible to suppress the uneven flow of the DC current. Thus, the configuration can suppress local heat generation. Further, since the width of each of the connecting portions 719E at both ends is wide, the facing area between the extending portion 718E and the mounting surface 500C can be increased. Thereby, it is possible to reduce the inductance.

Although the description is omitted, the semiconductor device 20 of the present embodiment can exhibit the same effect in the portion having the same configuration as the semiconductor device 20 described in the first embodiment.

The number of main terminals 71 is not limited to the above example. It may be an odd number or an even number. The number of the extending portions 718E is not limited to four. The total number of the main terminal 71C and the extending portion 718E of the main terminal 71E may be three or more.

The configuration of the present embodiment and the configuration of the second embodiment may be combined. The width of the portion alternately arranged with the main terminal 71C is made greater in the extending portions 718E at both ends than in the extending portion 718E in the center. In addition, the width of the connecting portion 719E is made greater in the extending portions 718E at both ends than in the extending portion 718E in the center.

The configuration of the present embodiment and the configuration of the third embodiment may be combined.

An example is shown in which all the extending portions 718E are connected to one electrode connection portion 717E, but the present embodiment is not limited thereto. For example, the main terminal 71E may be divided into two in the X direction, and the extending portion 718E may be connected to each of the electrode connection portions 717E.

An example is shown in which the width of the connecting portion 719E at the end is greater than the width of the connecting portion 719E at the center over the total length, but the present embodiment is not limited thereto. The width of the connecting portion 719E at the end is greater than the width of the connecting portion 719E at the center in a part of the range from the end connected to the electrode connection portion 717E.

### Other Embodiments

Although an example in which the semiconductor device 20 is applied to the inverter 5 has been described, the present embodiment is not limited to the above example. For example, the present embodiment may be applied to a converter. Further, the semiconductor module 10 can be also applied to both of the inverter 5 and the converter.

The example in which the IGBT 6i and the FWD 6d are formed on the semiconductor element 40 has been shown. However, it is not limited to this. The FWD 6d may be used as a separate chip.

The example in which the IGBT 6i is shown as the switching element has been shown. However, it is not limited to this. For example, a MOSFET may be employed.

The example in which the heat radiating surfaces 501C and 501E are exposed from the sealing resin body 30 has been shown. However, it is not limited to this. At least one of the heat radiating surfaces 501C and 501E may be covered with the sealing resin body 30. The configuration may be covered with an insulating member (not shown) different from the sealing resin body 30.

Although not shown, a through hole may be provided in the lead frame 70 at a portion facing the heat sink 50. Thereby, it is possible to avoid molding defects. For example, the main terminal 71 may be provided with a through hole. A through hole may be provided in the signal terminal 73. A through hole may be provided in the suspension lead 77.

An example of a double-sided heat dissipation structure has been shown as the semiconductor device 20, but the present disclosure is not limited thereto. It can be applied as long as all the main terminals 71 are drawn out from the side surface 302 of the sealing resin body 30. In the single-sided heat dissipation structure, for example, the main terminals 71C and 71E may be arranged alternately, and the width W1 of the external connection portions 712C and 712E may be greater than the width W2 of the boundary portions 713C and 713E.

In the above, the embodiments, the configurations, the aspects of the semiconductor device according to the present disclosure are exemplified. The present disclosure is not limited to the above-described embodiments, each configuration and each aspect related to the present disclosure. In addition, while the various combinations and configurations, other combinations and configurations, including more, less or only a single element, are also within the spirit and scope of the present disclosure.

What is claimed is:

1. A semiconductor device comprising:
at least one semiconductor element having, as main electrodes, a first main electrode and a second main electrode, and a main current flowing between the first main electrode and the second main electrode;
a sealing resin body that seals the at least one semiconductor element; and
a first main terminal and a second main terminal provided as a plurality of main terminals, the first main terminal being electrically connected to the first main electrode inside the sealing resin body, the second main terminal being electrically connected to the second main electrode inside the sealing resin body, and each of the plurality of main terminals extending to an outside of the sealing resin body for connecting to an external member, wherein
all of the plurality of main terminals protrude from one surface of the sealing resin body,
the first main terminal and the second main terminal are alternately arranged in one direction orthogonal to a thickness direction of the at least one semiconductor element such that a side surface of the first main terminal and a side surface of the second main terminal face each other,
a width in the one direction of each of the plurality of main terminals protruding from the one surface of the sealing resin body is greater in an external connection portion to which the external member is connected than in a boundary portion to which the sealing resin body is connected,
each of the plurality of main terminals includes a portion having a width greater than the width of the boundary portion between the boundary portion and the external connection portion, and
in an extending portion from the boundary portion to the external connection portion, a width of an arbitrary first position is equal to or greater than a width of an arbitrary second position closer to the sealing resin body than the arbitrary first position.

2. The semiconductor device according to claim 1, wherein
a number of the plurality of main terminals is an odd number,
the first main terminal and the second main terminal are alternately arranged with a predetermined gap, and
in the one direction, a width of each of two of the plurality of main terminals at both ends is smaller than a width of a main terminal between both ends.

3. The semiconductor device according to claim 1, further comprising
a first heat radiating member and a second heat radiating member as heat radiating members arranged so as to sandwich the at least one semiconductor element, wherein
the second main electrode is formed on a surface opposite to a surface on which the first main electrode is formed,
the first heat radiating member is electrically connected to the first main electrode, and
the second heat radiating member is electrically connected to the second main electrode.

4. The semiconductor device according to claim 3, wherein
the second main terminal includes an electrode connection portion connected to the second main electrode, and an extending portion including the boundary portion and the external connection portion and extending inside and outside the sealing resin body,
the plurality of main terminals includes at least a plurality of first main terminals or a plurality of extending portions,
the first main terminal and the extending portion are alternately arranged in the one direction,
the first main terminal is connected to the first main electrode via the first heat radiating member, and
the second heat radiating member is connected to the second main electrode via the second main terminal.

5. The semiconductor device according to claim 4, wherein
the second main terminal has three or more of the extending portions, and
in a predetermined extension region inside the sealing resin body from the electrode connection portion, a width of each of two of the extending portions arranged at both ends is greater than a width of an extension portion arranged between the both ends.

6. The semiconductor device according to claim 3, wherein
a width of terminal region including all the external connection portions is greater than a width of each of the heat radiating members.

7. The semiconductor device according to claim 1, wherein
each of the plurality of main terminals includes a narrowing portion, a widening portion, a connecting portion, and a tie bar mark as portions extending in a direction orthogonal to the one direction,
the narrowing portion includes the boundary portion, and arranged inside and outside the sealing resin body,
the widening portion includes the external connection portion, and has a width greater than a width of the narrowing portion,
the connecting portion connects the narrowing portion and the widening portion, and a width of the connecting portion increases toward the widening portion, and
the tie bar mark formed in the connecting portion and apart from the narrowing portion and the widening portion.
